(19) United States
(12) Patent Application Publication
(10) Pub. No.: US 2003/0059996 A1
(43) Pub. Date: Mar. 27, 2003

(54) Method for forming gate structure

(75) Inventors: Nien-Yu Tsai, Taipei (TW); Yung-Ching Wang, Kaohsiung (TW)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: ProMos Technologies Inc.

(21) Appl. No.: 10/060,590

(22) Filed: Jan. 30, 2002

(30) Foreign Application Priority Data
Sep. 25, 2001 (TW) 90123651

(51) Int. Cl. H01L 21/8238

(52) U.S. Cl. 438/200

(57) ABSTRACT

A method for forming a gate structure is provided. The forming method includes steps of providing a semiconductor substrate; forming an insulation layer, a first gate conductor layer, a second gate conductor layer, and a masking layer on the semiconductor substrate; removing portions of the masking layer, the semiconductor substrate, and the first gate conductor layer to define the gate structure by etching; executing a cleaning process to the semiconductor with a specific cleaning agent for etching the second gate conductor layer, thereby removing portions of the second gate conductor layer in the gate structure; and performing a thermal treatment process to the semiconductor substrate and forming an insulation spacer on the side surface of the gate structure.

### FIELD OF THE INVENTION

This invention relates to a method for forming a gate structure, and more particularly to a method for forming a gate structure in a semiconductor manufacturing process.

### BACKGROUND OF THE INVENTION

Please refer to FIGS. 1A-1D showing a gate structure manufacturing process of a metal-oxide-semiconductor transistor. Please refer to FIG. 1A. It shows removing portions of polysilicon player 121, tungsten silicide layer 122 (WSiₓ), and silicon nitride layer 123 which are formed on silicon substrate 10 and gate insulation layer 11 sequentially to define the gate structure by etching, and then forming a gate structure 13. After removing the residual polymers of the previous etching process by a cleaning process (as shown in FIG. 1B, it is usually performed with dilute hydrofluoric acid (DHF) solution), it follows the subsequent rapid thermal oxidation (RTO) and the silicon nitride spacer 14 performing processes (as shown in FIG. 1C). As shown clearly in FIG. 1C, the tungsten silicide layer 122 (WSiₓ) causes protrusions on both sides because of that the thermal expansion coefficients of polysilicon layer 121 and tungsten silicide layer 122 (WSiₓ) are different, and that after a process like the rapid thermal oxidation, the thermal expansion coefficient of tungsten silicide layer 122 (WSiₓ) becomes larger. Accordingly, it's very possible for the tungsten silicide layer 122 to expose through the loss of nitrogen silicide spacer 14, when manufacturing in the subsequent process contacts to the contact hole of the bit line. Because of the appearance of the tungsten silicide layer 122, a short circuit will occur with the subsequently filled contact conductor 15 (e.g., polysilicon or tungsten). Thus, devices will perform abnormally, and the pass rate of the product will be adversely influenced. It is therefore tried by the present invention to deal with this situation.

### SUMMARY OF THE INVENTION

It is an object of the present invention to provide a method for forming a gate structure of a metal-oxide-semiconductor transistor in the semiconductor manufacturing process.

It is another object of the present invention to provide a method to avoid the short circuit problem in a gate structure manufacturing process, wherein the short circuit problem is due to the protrusion of the second gate conductor.

It is another further object of the present invention to provide a cleaning agent capable of etching the second gate conductor to perform a cleaning process for the semiconductor substrate having the gate structure to avoid the short circuit problem during the manufacturing process.

The present invention provides a forming method for a gate structure. The forming method comprises the steps of providing a semiconductor substrate; forming an insulation layer, a first gate conductor layer, a second gate conductor layer, and a masking layer on the semiconductor substrate; removing portions of the masking layer, the semiconductor substrate, and the first gate conductor layer to define the gate structure by etching; performing a cleaning process to the semiconductor with a specific cleaning agent for etching the second gate conductor layer, thereby removing portions of the second gate conductor layer in the gate structure; and performing a thermal treatment process to the semiconductor substrate and forming an insulation spacer on the side surface of the gate structure.

Preferably, in the method for forming a gate structure, the semiconductor substrate is a silicon substrate.

Preferably, in the method for forming a gate structure, the insulation layer is a silicon oxide layer.

Preferably, in the method for forming a gate structure, the first gate conductor layer is a doped polysilicon layer.

Preferably, in the method for forming a gate structure, the second gate conductor layer is a tungsten silicide layer.

Preferably, in the method for forming a gate structure, the second gate conductor layer is removed about 10-15 nm in thickness by the cleaning process.

Preferably, in the method for forming a gate structure, the masking layer is a silicon nitride layer.

Preferably, in the method for forming a gate structure, the insulation spacer is a silicon nitride spacer.

Preferably, in the method for forming a gate structure, the cleaning agent is a mixture solution containing one of ammonium (NH₄OH) and potassium hydroxide (KOH).

Preferably, in the method for forming a gate structure, the cleaning agent allows the second gate conductor layer to be etched at a temperature ranged from 35° C. to 70° C.

Preferably, in the method for forming a gate structure, the cleaning process is performed at a temperature of 65° C.

Preferably, in the method for forming a gate structure, the cleaning process is performed for a time period ranged from 1 to 10 minutes.

Preferably, in the method for forming a gate structure, the cleaning process is performed for about 2 minutes.

Preferably, in the method for forming a gate structure, the cleaning agent is a mixture solution containing potassium hydroxide (KOH), hydrogen peroxide (H₂O₂), and non-ionic water in a ratio of 1:2:50.

Preferably, in the method for forming a gate structure, the cleaning agent is a mixture solution containing ammonium (NH₄OH), hydrogen peroxide (H₂O₂), and non-ionic water in a ratio of 1:2:50.

Preferably, in the method for forming a gate structure, the thermal treatment process is a rapid thermal oxidation.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1A˜1D are schematical views showing the known manufacturing process of a metal-oxide-semiconductor transistor gate structure; and

FIGS. 2A˜2D are schematical views showing the manufacturing process of a preferred embodiment of the metal-oxide-semiconductor transistor gate structure according to the present invention.

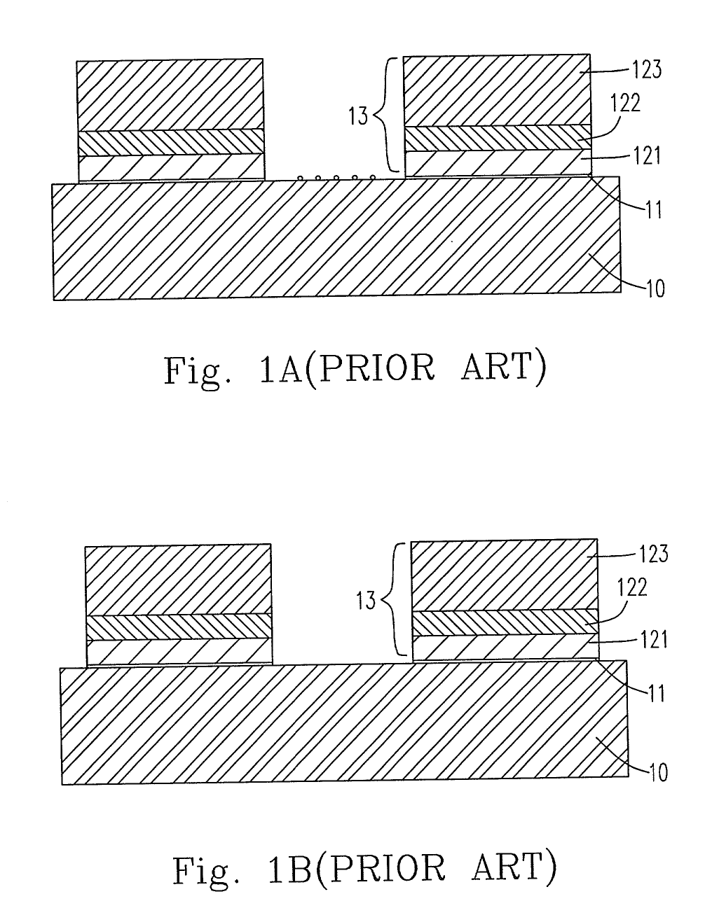

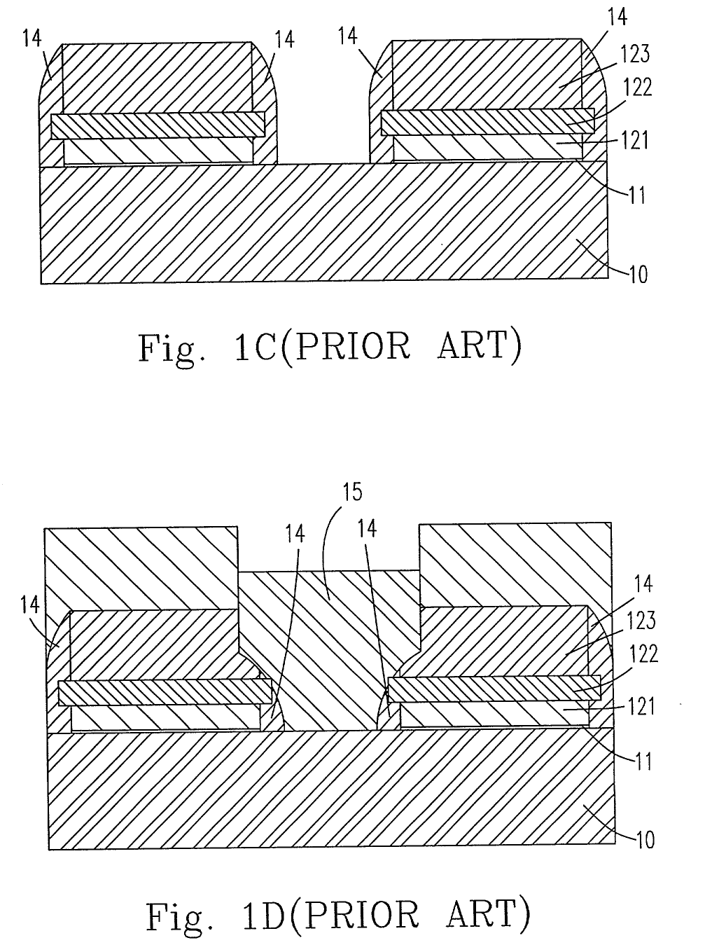

### DETAILED DESCRIPTION OF THE PREFERRED EMBODIMENT

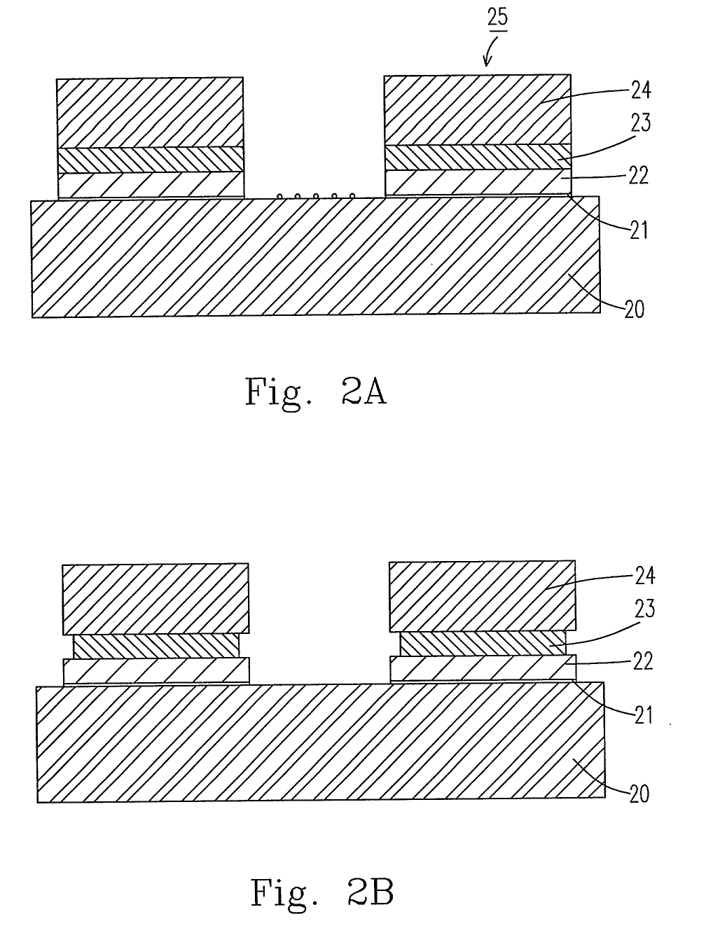

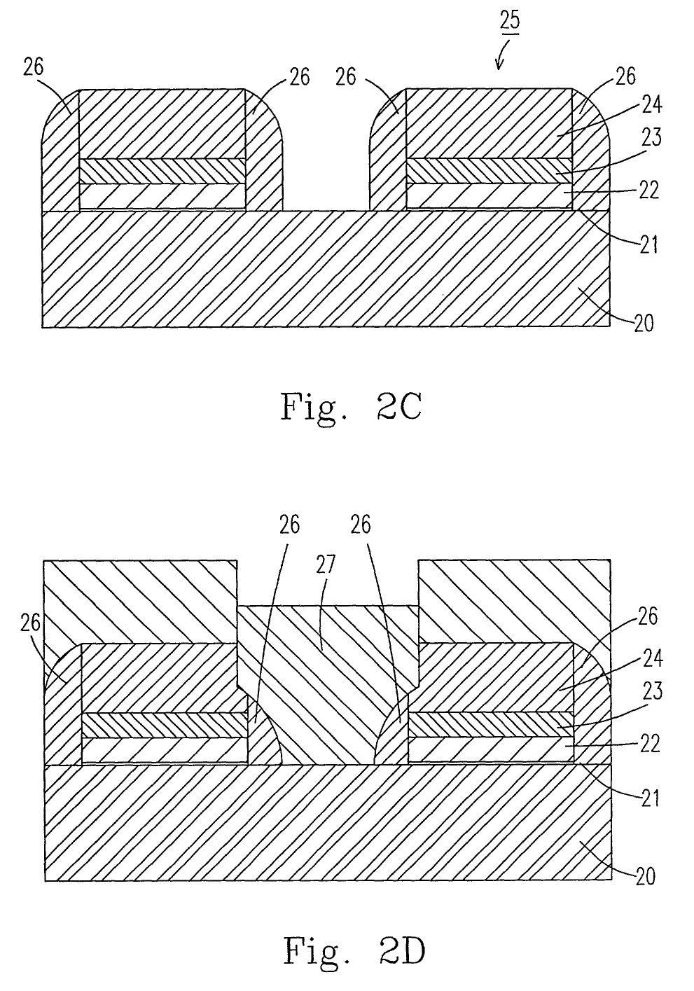

Please refer to FIGS. 2A-2D schematically showing the manufacturing process of a preferred embodiment of metal-oxide-semiconductor transistor according to the present invention. It provides a semiconductor substrate 20 (generally a silicon substrate) forming thereon an insulation layer 21 (generally a silicon oxide), a first gate conductor layer 22 (generally a heavily doped polysilicon), a second gate conductor layer 23 (generally a tungsten silicide), and a masking layer 24 (generally a silicon nitride. Through removing portions of masking layer 24, second gate conductor layer 23, and the first gate conductor layer 22 by anisoptic etching (as shown in FIG. 2A), the gate structure 25 is defined. In the subsequent thermal treatment process, there comes a problem of the second gate conductor 23 (generally tungsten silicide, WSiₓ) which will present protrusions on both sides when performing the known process. In order to overcome the above problem, the present invention uses the cleaning agent capable of etching the second gate conductor 23 to perform a cleaning process for the semiconductor substrate 20 having the gate structure 25. In addition to the removal of residual polymers in the previous etching process, parts of the second gate conductor layer 23 will be removed at the same time to form the structure as shown in FIG. 2B. It is clearly seen that the spacer of the second gate conductor layer 23 shrinks inward a distance because of the etching.

Please refer to FIG. 2C showing the above structure undergoing a thermal treatment process (e.g., rapid thermal oxidation) and forming an insulation spacer 26 (of silicon nitride generally). In FIG. 2C, the second gate conductor layer 23 will present protrusions on both sides due to the larger thermal expansion coefficient, but the protrusion of the spacer surface will not occur. Thus, there is no possibility to expose the second gate conductor layer 23 through the loss of the insulation spacer 26, upon manufacturing contacts to the contact hole of the bit line in the subsequent process (as shown in FIG. 2D). Accordingly, the subsequently filled contact conductor 27 (e.g., polysilicon or tungsten) can keep in good insulation condition therewith, and thus improve the pass rate of the products effectively. It will get to the main purpose of the present invention and totally overcome the shortcoming of the prior art.

The semiconductor substrate applied in the present preferred embodiment can be a silicon substrate. The insulation layer can be a silicon oxide layer. The first gate conductor layer can be a heavily doped polysilicon. The second gate conductor layer can be a tungsten silicide layer. And the masking layer can be a silicon nitride layer. The cleaning agent is capable of etching the tungsten silicide layer at a temperature ranged from 35° C. to 70° C. (preferably about 65° C.) and can be a mixture solution containing one of ammonium (NH₄OH) and potassium hydroxide (KOH). The cleaning agent applied in the present preferred embodiment can be a mixture solution containing potassium hydroxide (KOH) or ammonium (NH₄OH), hydrogen peroxide (H₂O₂), and de-ionic water in a ratio of 1:2:50. The cleaning process can be performed for a time period ranged from 1 to 10 minutes.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for forming a gate structure in a semiconductor manufacturing process, comprising steps of:
providing a semiconductor substrate;
forming an insulation layer, a first gate conductor layer, a second gate conductor layer, and a masking layer on said semiconductor substrate;
removing portions of said masking layer, said second gate conductor layer, and said first gate conductor layer to define said gate structure by etching;
executing a cleaning process to said semiconductor substrate with a specific cleaning agent for etching said second gate conductor layer, thereby removing portions of said second gate conductor layer in said gate structure; and
performing a thermal treatment process to said semiconductor substrate and forming an insulation spacer on the side surface of said gate structure.

2. The method according to claim 1 wherein said semiconductor substrate is a silicon substrate.

3. The method according to claim 1 wherein said insulation layer is a silicon oxide layer.

4. The method according to claim 1 wherein said first gate conductor layer is a doped polysilicon.

5. The method according to claim 1 wherein said second gate conductor layer is a tungsten silicide layer.

6. The method according to claim 1 wherein said second gate conductor layer is removed about 10-15 nm in thickness by said cleaning process.

7. The method according to claim 1 wherein said masking layer is a silicon nitride layer.

8. The method according to claim 1 wherein said insulation spacer is a silicon nitride spacer.

9. The method according to claim 1 wherein said cleaning agent is a mixture solution containing one of ammonium (NH₄OH) and potassium hydroxide (KOH).

10. The method according to claim 1 wherein said cleaning agent allows said second gate conductor layer to be etched at a temperature ranged from 35° C. to 70° C.

11. The method according to claim 1 wherein said cleaning process is performed at a temperature of 65° C.

12. The method according to claim 1 wherein said cleaning process is performed for a time period ranged from 1 to 10 minutes.

13. The method according to claim 1 wherein said cleaning process is performed for about 2 minutes.

14. The method according to claim 1 wherein said thermal treatment process is a rapid thermal oxidation.

15. The method according to claim 1 wherein said cleaning agent is a mixture solution containing potassium hydroxide (KOH), hydrogen peroxide (H₂O₂), and de-ionic water in a ratio of 1:2:50.

16. The method according to claim 1 wherein said cleaning agent is a mixture solution containing ammonium (NH₄OH), hydrogen peroxide (H₂O₂), and de-ionic water in a ratio of 1:2:50.

17. The method according to claim 1 wherein said portions of said masking layer, said second gate conductor layer, and said first gate conductor layer are removed by anisoptic etching.
